(19) United States
(12) Patent Application Publication
(10) Pub. No.: US 2026/0266633 A1
(43) Pub. Date: Sep. 10, 2026

(54) METHODS AND APPARATUS TO DEFINE AN INTERCONNECT NODE FOR A SUBMERSIBLE SENSING CABLE

(71) Applicant: The Boeing Company, Arlington, VA (US)

(72) Inventors: Michael Douglas Holt, Elon, NC (US); Thomas Ian Manning, Herndon, VA (US); Alexander Arman Serpen, Ashburn, VA (US); Jeffrey Scott Willcox, Arlington, MA (US); Luke Beatman, Santa Cruz, CA (US)

(21) Appl. No.: 19/072,631

(22) Filed: Mar. 6, 2025

(51) Int. Cl. G01D 11/24; G01D 11/30; G01V 1/38; H02G 15/18

(52) U.S. Cl. CPC G01D 11/245; G01D 11/30; G01V 1/3843; H02G 15/18; G01V 2210/1423

(57) ABSTRACT

Systems, apparatus, articles of manufacture, and methods are disclosed to define an interconnect node for a submersible sensing cable. In some examples, the interconnect node includes a first termination mount defining a first wire termination to be electrically coupled to a first wire portion; a second termination mount defining a second wire termination to be electrically coupled to a second wire portion; a first circuit board having (i) a first end coupled to the first termination mount and (ii) a second end opposite the first end of the first circuit board, the second end of the first circuit board coupled to the second termination mount.

### FIELD OF THE DISCLOSURE

This disclosure relates generally to submersible sensing cables and, more particularly, to methods and apparatus to define an interconnect node for a submersible sensing cable.

### BACKGROUND

In recent years, sensing cables attached to marine vessels have collected data corresponding to acoustics and/or movement beneath the ocean surface. These sensing cables are towed behind a marine vessel to collect the data from beneath the ocean surface. In known implementations, these sensing cables are implemented as a continuous oil-filled hose. In particular, the oil-filled hose includes a plastic casing housing sensors as well as electronic components submerged in oil.

Because the oil-filled hose is a continuous hose without a defined demarcation, the oil-filled hose requires precise and specialized labor to repair, as well as significant production labor time, all of which can be costly. Additionally, the general infrastructure required to fabricate oil-filled hose configurations require a significant investment in retooling to adjust sensor locations (e.g., reconfigure the aperture) in a full production environment.

### SUMMARY

An apparatus to define an interconnect node for a submersible sensing cable. The apparatus includes a first termination mount defining a first wire termination to be electrically coupled to a first wire portion. The apparatus further includes a second wire termination mount defining a second wire termination to be electrically coupled to a second wire portion. The apparatus further includes a circuit board having (i) a first end coupled to the first termination mount and (ii) a second end opposite the first end of the circuit board. The second end of the circuit board is coupled to the second termination mount.

A submersible sensing cable including a jacket and a node defined by the jacket. The node separates first and second wire portions of the sensing cable. The submersible sensing cable further includes a first mechanical support to define a first end of the node and a second mechanical support to find a second end of the node opposite the first end. The submersible sensing cable further includes a circuit board extending between the first and second mechanical supports. The submersible sensing cable further includes a sensor electrically coupled to the circuit board. The submersible sensing cable further includes a potting material filler at least partially surrounding the circuit board.

A method for producing a submersible sensing cable including coupling a circuit board to a first support at a first end of the circuit board and coupling the circuit board to a second support at a second end of the circuit board opposite of the first end of the circuit board. The method further includes terminating a first wire portion to the first support and terminating a second wire portion to the second support. The method further includes providing a potting material to at least partially surround the circuit board.

### BRIEF DESCRIPTION OF THE DRAWINGS

FIG. 1 is an example system in which examples disclosed herein can be implemented.

FIG. 2 depicts an example interconnect node in accordance with teaching of this disclosure.

FIG. 3 is a second diagram of the example interconnect node of FIG. 2.

FIG. 4 is an example termination mount of the interconnect node of FIGS. 2 and 3.

FIG. 5 is an example connection that can be implemented in examples disclosed herein.

FIG. 6 is an example method to produce examples disclosed herein.

FIG. 7A-7E illustrate an example process of securing a wire to a termination mount that can be implemented in examples disclosed herein.

In general, the same reference numbers will be used throughout the drawings and accompanying written description to refer to the same or like parts. The figures are not necessarily to scale.

### DETAILED DESCRIPTION

Methods and apparatus to define an interconnect node for a submersible sensing cable are disclosed. Submersible sensing cables are typically utilized to gather data from beneath the ocean surface. In some known implementations, submersible sensing cables can gather pressure data, acoustic data, vision data, and/or movement data. Often, submersible sensing cables can be utilized to track submersible vessels (e.g., submarines), aquatic creatures (e.g., whales, etc.), and/or weather patterns.

In known implementations, a hose including wire components utilizing an oil-filled cavity has been towed by marine vessels to collect data. The hose is typically composed of relatively long and contiguous sections that define the oil-filled cavity that are difficult to sleave and/or de-sleave. Therefore, the oil-filled hose can be difficult and expensive to repair or service as the hose must generally be dismantled in totality for repair. Further, the oil-filled hose can be relatively fragile in relatively rougher ocean conditions.

Examples disclosed herein enable a highly configurable submersible sensing cable that can be towed by a marine vessel. The submersible sensing cable of the present disclosure includes termination mounts where a circuit board is coupled at opposite ends to the termination mounts. As a result, the circuit board forms a structural body of the interconnect node. In some examples, the use of the circuitry as a component in the strength of the system is implemented in relatively low tension and/or relatively low speed towing applications (e.g., autonomous vehicles, fixed sensing systems, etc.). Further, the interconnect node can be coupled to wire portions to electrically and/or communicatively couple interconnect nodes of the sensing cable. Therefore, an amount of interconnect nodes as well as distances therebetween can be customizable and adjustable. Further, the interconnect nodes can be coupled and/or de-coupled based on a desired usage. In some examples, each interconnect node is surrounded and/or encapsulated in a potting material for increase strength, water tightness, and durability. Further, the interconnect node can include buoyant material for deployment in diverse ocean settings.

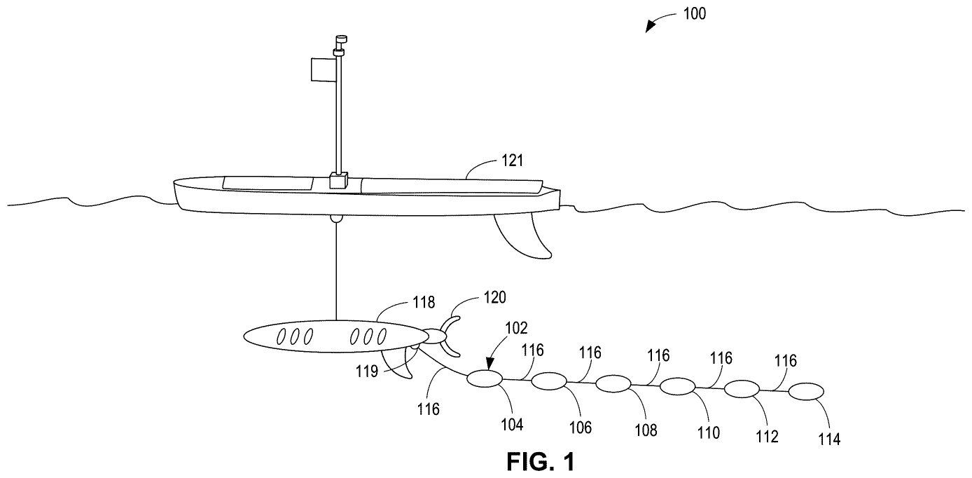

FIG. 1 is an example system 100 to collect data from beneath the ocean surface in which examples disclosed herein can be implemented. In the view of FIG. 1, a sensing cable 102 includes example interconnect nodes 104, 106, 108, 110, 112, and 114. While six interconnect nodes 104, 106, 108, 110, 112, and 114 are shown in FIG. 1, the sensing cable 102 can include any other appropriate number of interconnect nodes. The various interconnect nodes 104, 106, 108, 110, 112, 114 of the sensing cable 102 enable configurability and reparability as opposed to previous inflexible conventional systems.

The interconnect nodes 104, 106, 108, 110, 112, 114 include at least one sensor to collect data from beneath the ocean surface. The sensing cable 102 further includes example cable portions 116 between the interconnect nodes 104, 106, 108, 110, 112, 114 as well as an example submersible propulsion unit 118. The cable portions 116 between the interconnect nodes 104, 106, 108, 110, 112, 114 can include a wire and/or wire portions for data transmission between the interconnect nodes 104, 106, 108, 110, 112,114. Further, the cable portions 116 can include foam (e.g., ballast foam) around the wire on the inside of the cable portions 116 or on the outside of the cable portions 116.

The sensing cable 102 is further coupled to the submersible propulsion unit 118. The submersible propulsion unit 118 includes an example connection 119 to the sensing cable 102. In some examples, the submersible propulsion unit 118 can capture wave energy to pull the sensing cable 102 through the water. In other examples, the submersible propulsion unit 118 can utilize an example motor 120 to tow the sensing cable 102 through the water.

The submersible propulsion unit 118 is coupled and/or tethered to an example marine vessel 121. The marine vessel 121 can be located above, on, and/or below the ocean surface. The marine vessel 121 can be instantiated by, but is not limited to, any one of a submersible marine vessel (e.g., a submarine, etc.), an engine-driven marine vessel (e.g., a motorboat, etc.), a wave-driven marine vessel (e.g., a vessel propelled by wave energy, etc.), a solar-driven marine vessel (e.g., a vessel propelled by solar energy, etc.), a wind-driven vessel (e.g., a sailboat, an autonomous sailing vessel, a vessel propelled by wind energy, etc.), and/or any other appropriate type of marine vessel.

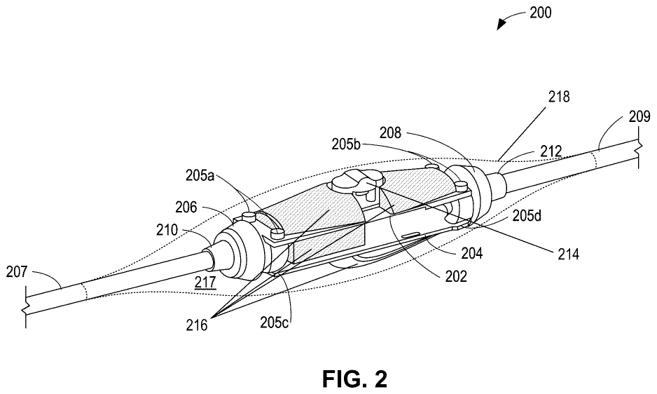

As will be discussed in connection below with FIGS. 2-6, examples disclosed herein enable a sensing cable that collects data from beneath the surface of the ocean. The sensing cable includes at least one interconnect node with sensors to capture data. The interconnect nodes are highly configurable and adjustable such that the sensing cable can be modified to adjust a number of the interconnect nodes. The number of interconnect nodes can be adjusted so that the sensing cable can include more or less interconnect nodes. Additionally, the nodes can be placed precisely to maintain spacing, either constant or variable, between various interconnect nodes. Further, the interconnect nodes provide robustness and reparability with relative ease due to the modifiable nature of the interconnect nodes.

FIG. 2 depicts an example interconnect node 200 in accordance with teachings of this disclosure. The interconnect node 200 is a single interconnect node 200 of the sensing cable 102 and can correspond to any of the interconnect nodes 104, 106, 108, 110, 112, 114 shown in FIG. 1. The illustrated view of FIG. 2 depicts the example interconnect node 200 having a first circuit board 202 and a second circuit board 204. However, in some examples, the interconnect node 200 can include one circuit board or more than two circuit boards. Additionally or alternatively, a plate or block (e.g., a metal component, a sheet metal component, composite, plastic, or other rigid material that can meet the structural requirements of the tow cable is placed between the interconnect nodes (e.g., in parallel with a circuit board). Further, additionally or alternatively, the interconnect node 200 can be shaped as a beam, a block, a plate, or any other suitable shape to meet the structural requirements of the tow cable.

In this example, the first circuit board 202 and the second circuit board 204 extend between a first termination mount 206 (e.g., a first mechanical support, a first bracket, etc.) and a second termination mount 208 (e.g., a second mechanical support, a second bracket, etc.). According to examples disclosed herein, the first circuit board 202 and the second circuit board 204 extend between the first termination mount 206 and the second termination mount 208 such that opposite ends of the first circuit board 202 and the second circuit board 204 are coupled to the first termination mount 206 and the second termination mount 208. As a result, a box-like structure is formed for increased strength. In some examples, the first circuit board 202 and the second circuit board 204 extend parallel to each other and bisect the interconnect node 200 longitudinally.

The first termination mount 206 and the second termination mount 208 are electrically coupled to a first wire portion 207 and a second wire portion 209, respectively. While two of the circuit boards 202, 204 are shown in the illustrated example of FIG. 2, any other appropriate number of circuit boards can be utilized (e.g., one, three, four, five, . . . , ten, . . . twenty, etc.)

By coupling opposite ends of the first circuit board 202 and the second circuit board 204 to the termination mounts 206, 208, the first circuit board 202 and the second circuit board 204 extend along longitudinal directions of the interconnect node 200 of the sensing cable 102 of FIG. 1. In some examples, the first circuit board 202 and the second circuit board 204 extend along a relatively parallel direction (e.g., within 10 degrees) with respect to each other. However, in other examples, the first circuit board 202 and the second circuit board 204 can extend between the first termination mount 206 and the second termination mount 208 at any orientation and/or at differing orientations from one another.

In some examples, the first end of the first circuit board 202 is coupled to the first termination mount 206 via a first fastener 205a and the second end of the first circuit board 202 is coupled to the second termination mount 208 via a second fastener 205b. Further, in some examples, the first end of the second circuit board 204 is coupled to the first termination mount 206 via a third fastener 205c and the second end of the second circuit board 204 is coupled to the second termination mount 208 via a fourth fastener 205d. In some examples, the first fastener 205a, the second fastener 205b, the third fastener 205c, and the fourth fastener 205d can be implemented by screws, bolts, clips, and/or any other fastening means to secure the first circuit board 202 and the second circuit board 204 to the first termination mount 206 and the second termination mount 208. Further, while the illustrated example of FIG. 2 depicts two first fasteners 205a and two second fasteners 205b, any appropriate number of fasteners can be used to secure the first circuit board 202 and/or the second circuit board 204 to the termination mounts 206, 208.

The interconnect node 200 fastens onto opposite ends of the cable portions 116 so that the sensing cable 102 joins multiple ones of the interconnect nodes 104, 106, 108, 110, 112, 114 of FIG. 1 together. In some examples, the interconnect nodes 104, 106, 108, 110, 112, 114 are coupled to the cable portions 116 via the first termination mount 206 and the second termination mount 208 on opposite sides of the interconnect node 200. In some examples, the first termination mount 206 and the second termination mount 208 include a first mechanical connection 210 and a second mechanical connection 212 on opposite sides of the interconnect node 200. According to examples disclosed herein, the first mechanical connection 210 and the second mechanical connection 212 span between the interconnect node 200 and the corresponding cable portions 116. By coupling the interconnect nodes 104, 106, 108, 110, 112, 114 to the cable portions 116 via the termination mounts 206, 208, the sensing cable 102 is adjustable and serviceable so that various interconnect nodes can be added, re-positioned, and/or removed from the sensing cable 102.

The example interconnect node 200 further includes a pressure sensor 214 mounted to a top of the first circuit board 202 (in the view of FIG. 2). In some examples, the pressure sensor 214 is electrically coupled to the first circuit board 202 and/or the second circuit board 204. The pressure sensor 214 can be exposed to the ocean. Additionally or alternatively, the pressure sensor 214 can measure temperature (e.g., a pressure-temperature sensor). While the pressure sensor 214 is implemented in the example of FIG. 2, other appropriate type of sensors (e.g., an acoustic sensor, a temperature sensor, etc.) may, additionally or alternatively, be implemented in the interconnect node 200.

The example interconnect node 200 further includes a ballast 216 (e.g., ballast foam, ballast material, foam, etc.) for buoyancy of the interconnect node 200. The amount or quantity of the ballast 216 may be increased or decreased to define a buoyancy of the interconnect node 200 more or less buoyant based on the desired flotation level of the sensing cable 102. The ballast 216 is sized, placed, and/or adjusted to make the interconnect node 200 have a neutral buoyancy. Neutral buoyancy for the interconnect node 200 can be reached when a force defined by the buoyancy of the interconnect node 200 is substantially equal to the weight of the interconnect node 200. In these examples, the ballast 216 is adjusted so that the buoyancy force produced due to the ballast 216 is substantially equal to the weight of the interconnect node 200 when submerged.

In some examples, the ballast 216 is contoured to at least partially define a rounded and/or elliptical shape of the interconnect node 200 when viewed along a longitudinal axis of the interconnect node 200. However, the interconnect node 200 can be formed in other shapes and configurations (e.g., rectangle shaped, oval shaped, tear-drop shaped, etc.) when viewed along the longitudinal axis of the interconnect node 200. In some examples, the ballast 216 can be positioned in between the first circuit board 202 and the second circuit board 204. Additionally or alternatively, the ballast 216 can be placed to completely or partially surround the first circuit board 202 and the second circuit board 204. As shown in the illustrated example of FIG. 2, the ballast 216 is positioned between the first circuit board 202 and the second circuit board 204 and on opposite surfaces of the first circuit board 202 and the second circuit board 204. In the example of FIG. 2, the ballast 216 is arranged to border the pressure sensor 214 so that it does not block the pressure sensor 214 from being exposed to the ocean and/or the exterior surface of the interconnect node 200. Additionally, the ballast 216 can be added between interconnect nodes (e.g., between an interconnect node 104 and an interconnect node 106, etc.) to adjust the buoyancy of the sensing cable 102.

The example interconnect node 200 further includes a potting material filler 217 to fill the interconnect node 200. The potting material filler 217 can further strengthen the interconnect node 200. In some examples, the potting material filler 217 fills a volume and/or a gap between the first circuit board 202 and the second circuit board 204. Additionally or alternatively, the potting material filler 217 can completely surround and/or partially surround the first circuit board 202 and the second circuit board 204.

In this example, the interconnect node 200 is further encapsulated by a molding 218 (e.g., a jacket). The molding 218 surrounds the entirety of the interconnect node 200 apart from a section around the pressure sensor 214. The molding 218 can be made from a waterproof and/or water-resistant material and may form watertight seals at the connections between the molding 218 and the first wire portion 207 and the second wire portion 209 at either end of the interconnect node 200. Further, the molding 218 may define a watertight seal along the border of the pressure sensor 214. In some other examples, the interconnect connect node can include one of the potting material filler 217 or the molding 218.

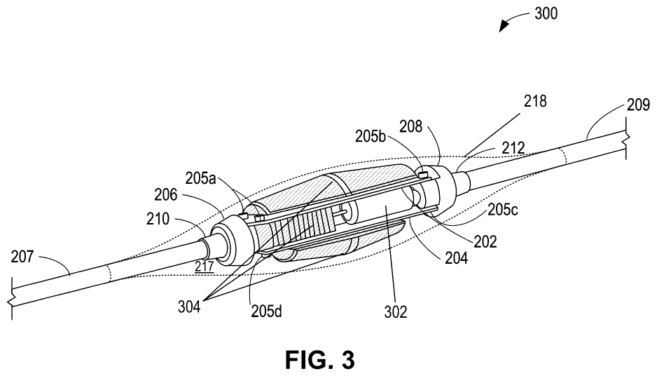

FIG. 3 is another alternative example interconnect node 300. Similar to the example of FIG. 2, the interconnect node 300 is a single interconnect node of the sensing cable 102 corresponding to any of the interconnect nodes 104, 106, 108, 110, 112, 114 of FIG. 1. Accordingly, the example interconnect node 300 includes the first circuit board 202, the second circuit board 204, the first fastener 205a, the second fastener 205b, the third fastener 205c, the fourth fastener 205d, the first termination point 206, the first wire portion 207, the second termination point 208, the second wire portion 209, the first mechanical connection 210, the second mechanical connection 212, the potting material filler 217, and the molding 218.

The example interconnect node 300 includes an acoustic sensor 302 (e.g., a hydrophone, etc.). In the illustrated example of FIG. 3, the acoustic sensor 302 is positioned in the space between the first circuit board 202 and the second circuit board 204 with a ballast 304 filling in at least a portion of the remaining space between the circuit boards 202, 204. In some examples, the potting material filler 217 may fill in any remaining spaces and/or gaps between the circuit boards 202, 204 and the acoustic sensor 302. While the example of FIG. 3 shows the acoustic sensor 302 located between the circuit boards 202, 204, the acoustic sensor 302 may be positioned in other positions within the interconnect node 300 (e.g., a surface of the circuit boards 202, 204, etc.). Further, while the acoustic sensor 302 is shown in FIG. 3, the interconnect node 300 can include any other appropriate type of sensor (e.g., a pressure sensor, a temperature sensor, etc.). The interconnect node 300 can additionally include the acoustic sensor 302 in combination with the pressure sensor 214 of FIG. 2 and/or any other combination of sensors. In some examples, the acoustic sensor 302 can be mechanically decoupled and/or isolated from the circuit boards 202, 204, so that towing forces transmitted through the circuit boards 202, 204 are not generally picked up as acoustic noise by the acoustic sensor 302.

The example interconnect node 300 further includes the ballast 304. The ballast 304 can be similar in function and composition to the example ballast 216 of FIG. 2. The ballast 304 is positioned between the first circuit board 202 and the second circuit board 204. However, in the illustrated example of FIG. 3, the ballast 304 is also positioned to cover a surface of the first circuit board 202 and the second circuit board 204. In this example, the ballast 304 covers an exterior surface of the circuit boards 202, 204 so that the ballast 304 forms a shape of the interconnect node 300. Similar to the interconnect node 200 of FIG. 2, the interconnect node 300 of FIG. 3 is in a rounded, ellipsoid, or tear-drop shape, when viewed along a longitudinal axis of the interconnect node 300. However, the interconnect node 300 can be formed in other shapes and configurations (e.g., rectangles, ovals, rectangular blocks, cylinders, etc.) when viewed along the longitudinal axis of the interconnect node 300.

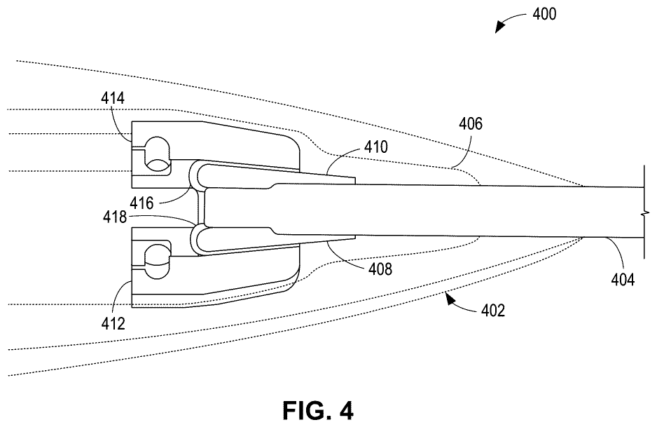

FIG. 4 is a detailed cross-sectional view of an example termination mount 400 (e.g., mechanical support) that can be implemented in examples disclosed herein. The termination mount 400 is encased in an example molding 402 that connects to an example cable 404. Further, the cable 404 terminates into the termination mount 400 via a mechanical connection 406. In this example, the cable 404 is fastened between a first clamp 408 and a second clamp 410. In particular, the first clamp 408 is coupled to the first circuit board via a first wedge body 412, while the second clamp 410 is coupled to the second circuit board via a second wedge body 414.

In the example of FIG. 4, the first clamp 408 and the second clamp 410 fasten the cable 404 in the termination mount 400 via a pressed fit. In particular, the first clamp 408 and the second clamp 410 form a wedge-shaped fit that constrains the cable 404 in place by applying force thereto. Accordingly, in some examples, the first clamp 408 and the second clamp 410 are angled relative to the longitudinal axis of the termination mount 400, and, as a result, the angles of the clamps 408, 410 increase an applied force to the cable 404. However, in other examples, the first clamp 408 and the second clamp 410 can restrain the cable 404 by compression of or piercing of the cable 404 and/or by any appropriate type of fastening. Further, material 416, 418 can be pinched and/or wedged in between the first wedge body 412 and the second wedge body 414, and the first clamp 408 and the second clamp 410. The material 416, 418 can be a durable fabric and/or other durable material. The material 416, 418 being wedged between the first wedge body 412 and the second wedge body 414 and the first clamp 408 and the second clamp 410, respectively, enables the towing of the interconnect node with the sensing cable as the interconnect node can withstand dragging forces against the termination mount 400.

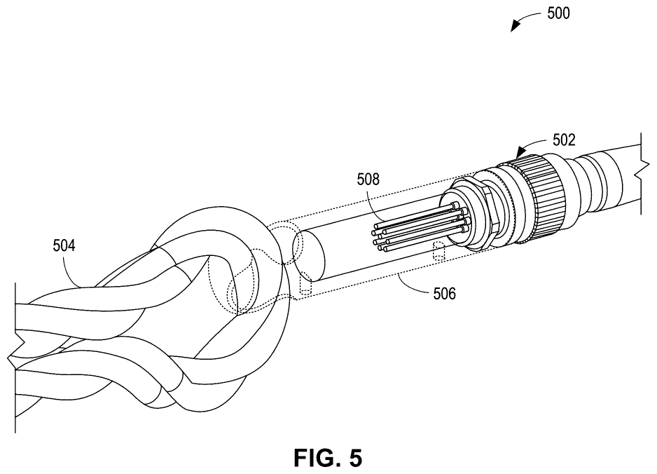

FIG. 5 shows an example connection that can be implemented in the examples herein. The connection is an example tail portion 500 of the sensing cable 102. The tail portion 500 can be positioned at an end of the sensing cable 102 at a relatively far distance from the connection 119 to the submersible propulsion unit 118 of FIG. 1. In some examples, a connection unit 502 of the tail portion 500 is coupled to a drogue 504 that can be lengthened (e.g., to increase drag) to ensure that the sensing cable 102 remains relatively straight while being towed behind the submersible propulsion unit 118.

The example connection unit 502 can further include a connector 506 and an electrical connector 508. The connector 506 can terminate at an end furthest from the sensing cable 102 with a circular receiving end to receive the drogue 504. In other examples, the connector unit 506 can terminate with a hook-and-eye closure, a plug receiver, and/or appropriate coupling implementation to couple (e.g., releasably couple) the drogue 504 to the connector unit 506.

The electrical connector 508 can be instantiated by a pin connector. The electrical connector 508 can be used to provide time domain reflectometry for breaks in the sensing cable 102, a point to manage voltage of the sensing cable 102, and an access point for data collected by the sensing cable 102.

The tail portion 500 can further include potting material (e.g., filler, etc.) to strengthen the tail portion 500 in between the connector 506 and the electrical connector 508.

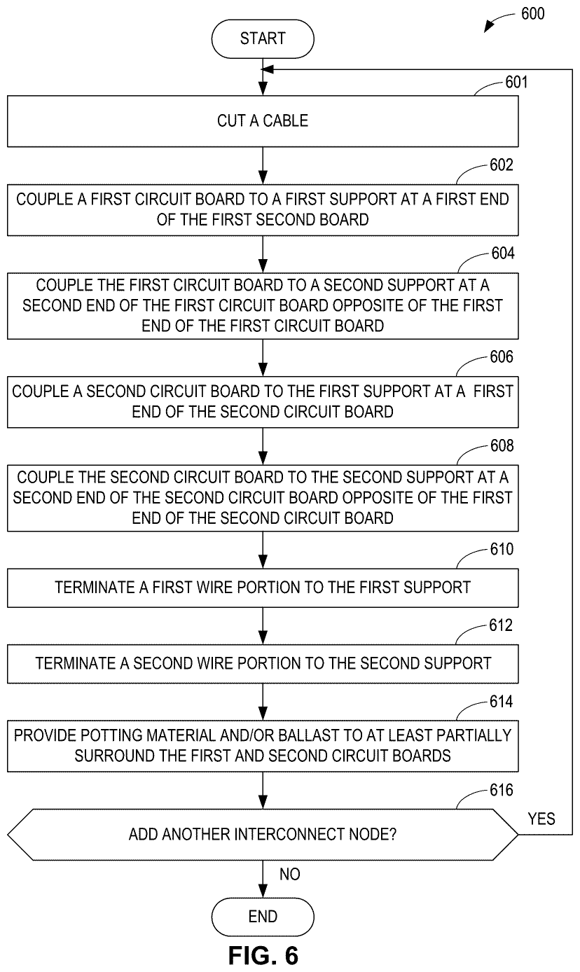

FIG. 6 is a flowchart representative of an example method 600 of producing and/or adjusting examples disclosed herein. In the example method 600 of FIG. 6, in some examples, the process begins at block 601, where a sensing cable is cut. In a particular example, an existing sensing cable can be cut to add or move an interconnect node (e.g., an adjustment process, a rework process, a repair process, etc.).

At block 602, a first circuit board is coupled to a first support at a first end of the first circuit board. In some examples, a first fastener couples the first circuit board to the first support.

At block 604, the first circuit board is coupled to a second support at a second end of the first circuit board opposite of the first end of the first circuit board. In some examples, a second fastener couples the first circuit board to the second support.

At block 606, a second circuit board is coupled to the first support at a first end of the second circuit board. In some examples, a third fastener couples the second circuit board to the first support.

At block 608, the second circuit board is coupled to the second support at a second end of the second circuit board opposite of the first end of the second circuit board. In some examples, a fourth fastener couples the second circuit board to the second support.

At block 610, a first wire portion is terminated to the first support, and, at block 612, a second wire portion is terminated to the second support. Additionally or alternatively, in some examples, the first wire portion terminates to the first circuit board, and the second wire portion terminates to the second circuit board. The termination of the first wire portion and the second wire portion results in a fastening of the wire within the first support and the second support. Accordingly, the interconnect node formed by this method can be coupled to other interconnect nodes on the sensing cable.

At block 614, in some examples, potting material can be provided to at least partially surround the first and second circuit boards. The potting material can strengthen the interconnect node. In some examples, ballast can be added to the interconnect node to provide buoyancy to the interconnect node. In some examples, the ballast is placed and/or added to achieve neutral buoyancy of the interconnect node.

At block 616, it is determined whether to add another interconnect node. If it is determined to add another interconnect node (block 616: YES), then the process restarts at block 602 to connect another interconnect node to the sensing cable. The process can be repeated any number of times. Further, according to examples disclosed herein, the interconnect nodes can be positioned at any interval, with even or uneven spacing, along the sensing cable. If it is determined not to add another interconnect node (block 616: NO), the process ends.

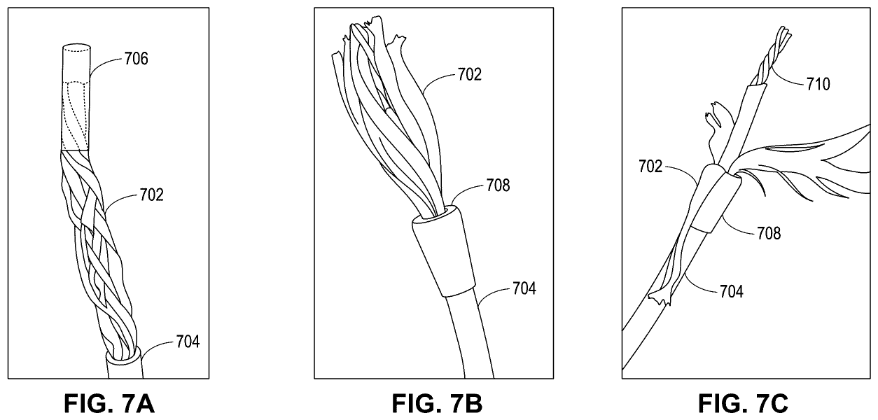

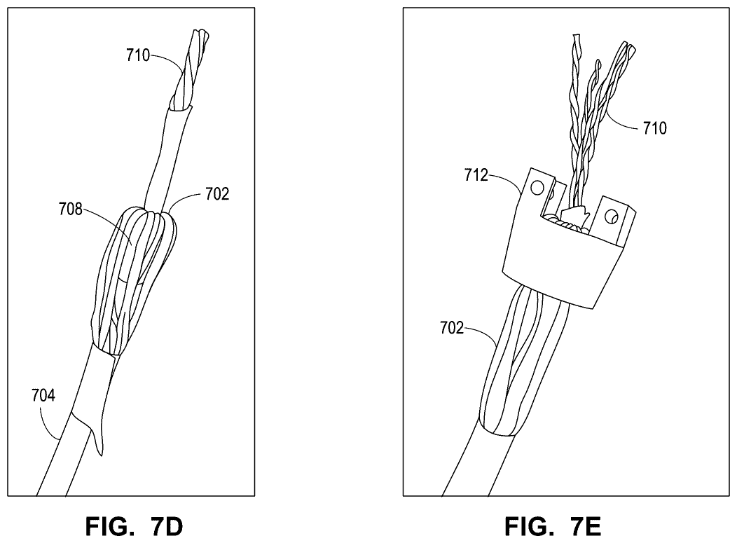

FIG. 7A-7E illustrate an example process of securing a wire to a termination mount. FIG. 7A depicts a fiber 702 extending from a casing 704. The fiber 702 terminates with straw 706.

Turning to FIG. 7B, an example wedge 708 is inserted to at least partially surround the fiber 702 and placed in contact with the casing 704. In turn, the straw 706 is removed from the fiber 702 after placement of the wedge 708.

The example of FIG. 7C depicts the fiber 702 being pulled back to at least partially expose and/or reveal a wire 710. In particular, the fiber 702 is pulled back until the wire 710 is exposed, as shown in FIG. 7D. Subsequently, the fiber 702 is coupled to the casing 704.

In the illustrated example of FIG. 7E, a termination mount 712 is slid over the wire 710 to pinch the fiber 702 between the casing 704 and the termination mount 712. Accordingly, the termination mount 712 compresses the fiber 702 to connect the wire portion to the termination mount 712 and, thus, enables the connection of various interconnect nodes in a relatively quick and cost-effective manner.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

Example methods, apparatus, systems, and articles of manufacture to define an interconnect node for a submersible sensing cable are described herein. Further examples and combinations thereof include the following:
Example 1 includes an apparatus to define an interconnect node for a submersible sensing cable, the apparatus comprising a first termination mount defining a first wire termination to be electrically coupled to a first wire portion, a second termination mount defining a second wire termination to be electrically coupled to a second wire portion, and a circuit board having (i) a first end coupled to the first termination mount and (ii) a second end opposite the first end of the circuit board, the second end of the circuit board coupled to the second termination mount.
Example 2 includes the apparatus as defined in example 1, wherein the circuit board is a first circuit board, and further including a second circuit board having (iii) a first end coupled to the first termination mount and (iv) a second end opposite the first end of the second circuit board, the second end of the second circuit board coupled to the second termination mount.
Example 3 includes the apparatus as defined in example 1 and example 2, further including a sensor electrically coupled to at least one of the first or second circuit boards.
Example 4 includes the apparatus as defined in example 3, wherein the sensor includes a pressure sensor.
Example 5 includes the apparatus as defined in example 3, wherein the sensor includes an acoustic sensor.
Example 6 includes the apparatus as defined in examples 1-5, wherein the interconnect node exhibits a rounded shape.
Example 7 includes the apparatus as defined in examples 1-6, further including a ballast material that is contoured to at least partially define the rounded shape.
Example 8 includes the apparatus as defined in examples 2-7, further including a potting material to at least partially surround the first and second circuit boards.
Example 9 includes the apparatus as defined in examples 1-8, further including a first fastener to couple the circuit board to the first termination mount and a second fastener to couple the circuit board to the second termination mount.
Example 10 includes a submersible sensing cable comprising a jacket, a node defined by the jacket, the node separating first and second wire portions of the sensing cable, a first mechanical support to define a first end of the node, a second mechanical support to define a second end of the node opposite the first end, a circuit board extending between the first and second mechanical supports, a sensor electrically coupled to the circuit board, and a potting material filler at least partially surrounding the circuit board.
Example 11 includes the sensing cable as defined in example 10, wherein the circuit board is a first circuit board, and further including a second circuit board extending between the first and second mechanical supports.
Example 12 includes the sensing cable as defined in example 11, wherein at least a portion of the potting material filler is positioned in a gap between the first and second circuit boards.
Example 13 includes the sensing cable as defined in example 11 and example 12, further including a first fastener to couple the first circuit board to the first mechanical support, a second fastener to couple the first circuit board to the second mechanical support, a third fastener to couple the second circuit board to the first mechanical support, and a fourth fastener to couple the second circuit board to the second mechanical support.
Example 14 includes the sensing cable as defined in examples 11-13, wherein the first and second circuit boards extend along a parallel direction across the node.
Example 15 includes the sensing cable as defined in examples 11-15, further including a ballast material that is contoured to at least partially define a rounded shape of the node.
Example 16 includes a method for producing a submersible sensing cable, the method comprising coupling a circuit board to a first support at a first end of the circuit board, coupling the circuit board to a second support at a second end of the circuit board opposite of the first end of the circuit board, terminating a first wire portion to the first support, terminating a second wire portion to the second support, and providing a potting material to at least partially surround the circuit board.
Example 17 includes the method of example 16, wherein the circuit board is a first circuit board, and further including coupling a second circuit board to the first support at a first end of the second circuit board, and coupling the second circuit board to the second support at a second end of the second circuit board opposite of the first end of the second circuit board.
Example 18 includes the method as defined in example 17, further including splicing the sensing cable to define a node corresponding to the first and second circuit boards.
Example 19 includes the method as defined in example 17 and example 18, further including placing a ballast material proximate the first and second circuit boards.
Example 20 includes the method as defined in examples 17-19, further including placing a sensor between the first and second circuit boards.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus to define an interconnect node for a submersible sensing cable, the apparatus comprising:
a first termination mount defining a first wire termination to be electrically coupled to a first wire portion;
a second termination mount defining a second wire termination to be electrically coupled to a second wire portion; and
a circuit board having (i) a first end coupled to the first termination mount and (ii) a second end opposite the first end of the circuit board, the second end of the circuit board coupled to the second termination mount.

2. The apparatus as defined in claim 1, wherein the circuit board is a first circuit board, and further including a second circuit board having (iii) a first end coupled to the first termination mount and (iv) a second end opposite the first end of the second circuit board, the second end of the second circuit board coupled to the second termination mount.

3. The apparatus as defined in claim 2, further including a sensor electrically coupled to at least one of the first or second circuit boards.

4. The apparatus as defined in claim 3, wherein the sensor includes a pressure sensor.

5. The apparatus as defined in claim 3, wherein the sensor includes an acoustic sensor.

6. The apparatus as defined in claim 1, wherein the interconnect node exhibits a rounded shape.

7. The apparatus as defined in claim 6, further including a ballast material that is contoured to at least partially define the rounded shape.

8. The apparatus as defined in claim 2, further including a potting material to at least partially surround the first and second circuit boards.

9. The apparatus as defined in claim 1, further including a first fastener to couple the circuit board to the first termination mount and a second fastener to couple the circuit board to the second termination mount.

10. A submersible sensing cable comprising:
a jacket;
a node defined by the jacket, the node separating first and second wire portions of the sensing cable;
a first mechanical support to define a first end of the node;
a second mechanical support to define a second end of the node opposite the first end;
a circuit board extending between the first and second mechanical supports;
a sensor electrically coupled to the circuit board; and
a potting material filler at least partially surrounding the circuit board.

11. The sensing cable as defined in claim 10, wherein the circuit board is a first circuit board, and further including a second circuit board extending between the first and second mechanical supports.

12. The sensing cable as defined in claim 11, wherein at least a portion of the potting material filler is positioned in a gap between the first and second circuit boards.

13. The sensing cable as defined in claim 11, further including:
a first fastener to couple the first circuit board to the first mechanical support;
a second fastener to couple the first circuit board to the second mechanical support;
a third fastener to couple the second circuit board to the first mechanical support; and
a fourth fastener to couple the second circuit board to the second mechanical support.

14. The sensing cable as defined in claim 11, wherein the first and second circuit boards extend along a parallel direction across the node.

15. The sensing cable as defined in claim 10, further including a ballast material that is contoured to at least partially define a rounded shape of the node.

16. A method for producing a submersible sensing cable, the method comprising:
coupling a circuit board to a first support at a first end of the circuit board;
coupling the circuit board to a second support at a second end of the circuit board opposite of the first end of the circuit board;
terminating a first wire portion to the first support;
terminating a second wire portion to the second support; and
providing a potting material to at least partially surround the circuit board.

17. The method of claim 16, wherein the circuit board is a first circuit board, and further including:
coupling a second circuit board to the first support at a first end of the second circuit board; and
coupling the second circuit board to the second support at a second end of the second circuit board opposite of the first end of the second circuit board.

18. The method as defined in claim 17, further including splicing the sensing cable to define a node corresponding to the first and second circuit boards.

19. The method as defined in claim 17, further including placing a ballast material proximate the first and second circuit boards.

20. The method as defined in claim 17, further including placing a sensor between the first and second circuit boards.
